(19) United States
(12) Patent Application Publication
(10) Pub. No.: US 2022/0415748 A1
(43) Pub. Date: Dec. 29, 2022

(54) SEMICONDUCTOR DEVICE AND POWER CONVERTER

(71) Applicant: Mitsubishi Electric Corporation, Tokyo (JP)

(72) Inventor: Yo TANAKA, Chiyoda-ku, Tokyo (JP)

(73) Assignee: Mitsubishi Electric Corporation, Tokyo (JP)

(21) Appl. No.: 17/793,936

(22) PCT Filed: Jan. 30, 2020
(86) PCT No.: PCT/JP2020/003535

§ 371 Date: Jul. 20, 2022

(51) Int. Cl. H01L 23/367; H01L 23/053; H05K 3/32

(52) U.S. Cl. CPC H01L 23/3675; H01L 23/053; H05K 3/321

(57) ABSTRACT

A semiconductor device includes a semiconductor element, a joint material, a heat spreader, and a sealing resin. The semiconductor element includes a main surface. The main surface has a first outer periphery. The sealing resin seals the semiconductor element, the joint material, and the heat spreader. The heat spreader includes a main body and a protrusion. The protrusion is joined to the main surface by the joint material. The main surface has an exposed surface. The exposed surface is located between the first outer periphery and the joint material. The first outer periphery and the exposed surface are exposed from the joint material. The first outer periphery and the exposed surface are sealed with the sealing resin.

### TECHNICAL FIELD

The present disclosure relates to a semiconductor device and a power converter.

### BACKGROUND ART

There has been a semiconductor device having a semiconductor element joined, by a joint material, to a heat spreader formed from a metal having a high thermal conductivity, for the purpose of reducing the size of the semiconductor device and promoting heat dissipation. The heat spreader, the semiconductor element, and the joint material are scaled with a scaling resin.

For example, Japanese Patent Laying-Open No. H9-8209 (PTL 1) discloses a semiconductor device including a heat dissipation member (heat spreader), an Ag (silver) paste (joint material), a semiconductor chip (semiconductor element), a molding resin (sealing resin), a tab, and an adhesive. The Ag paste is disposed inside the outer periphery of the semiconductor chip. The semiconductor chip has an exposed surface located between the outer periphery of the semiconductor chip and the Ag paste. The outer periphery and the exposed surface are exposed from the Ag paste.

The tab is located inside the outer periphery of the semiconductor chip, and disposed between the semiconductor chip and the heat dissipation member. The tab has one end joined to the semiconductor chip by the Ag paste. The tab has the other end joined to the heat dissipation member by the adhesive. Thus, the semiconductor chip is connected to the heat dissipation member through the Ag paste, the tab, and the adhesive.

### CITATION LIST

### Patent Literature

PTL 1: Japanese Patent Laying-Open No. H9-8209

### SUMMARY OF INVENTION

### Technical Problem

In the semiconductor device disclosed in the above-identified publication, the outer periphery (first outer periphery) and the exposed surface of the semiconductor chip (semiconductor element) are exposed from the Ag paste (joint material), and therefore, a thermal stress generated at an edge of the semiconductor chip may be reduced. The semiconductor chip is connected to the heat dissipation member (heat spreader) through the Ag paste, the tab, and the adhesive. Thus, the semiconductor chip and the heat dissipation member are not directly joined to each other by the Ag paste. It is therefore difficult to precisely arrange the semiconductor chip and the heat dissipation member.

The present disclosure is given in view of the above problem, and an object of the present disclosure is to provide a semiconductor device and a power converter that enable reduction of a thermal stress generated at an edge of the semiconductor element, and enable precise arrangement of the semiconductor element and the heat spreader.

### Solution to Problem

A semiconductor device of the present disclosure includes a semiconductor element, a joint material, a heat spreader, and a scaling resin. The semiconductor element includes a main surface. The main surface has a first outer periphery. The joint material is disposed on the main surface. The heat spreader is joined to the main surface by the joint material. The scaling resin seals the semiconductor element, the joint material, and the heat spreader. The heat spreader includes a main body and a protrusion. The main body is disposed opposite to the semiconductor element with respect to the joint material. The protrusion is located inside the first outer periphery and protrudes from the main body toward the main surface. The protrusion is joined to the main surface by the joint material. The main surface has an exposed surface. The exposed surface is located between the first outer periphery and the joint material. The first outer periphery and the exposed surface are exposed from the joint material. The first outer periphery and the exposed surface are sealed with the sealing resin.

### Advantageous Effects of Invention

In the semiconductor device of the present disclosure, the first outer periphery and the exposed surface are exposed from the joint material. Therefore, a thermal stress generated at an edge of the semiconductor element can be reduced. Moreover, the protrusion is joined to the main surface by the joint material. Therefore, the semiconductor element and the heat spreader are directly joined to each other by the joint material. Accordingly, the semiconductor element and the heat spreader can be arranged precisely.

### BRIEF DESCRIPTION OF DRAWINGS

FIG. 1 is a cross-sectional view schematically showing a first configuration of a semiconductor device according to Embodiment 1.

FIG. 2 is a cross-sectional view along a line II-III in FIG. 1.

FIG. 3 is an enlarged view of a region III in FIG. 1.

FIG. 4 is an enlarged view corresponding to FIG. 3 and schematically showing a second configuration of the semiconductor device according to Embodiment 1.

FIG. 5 is an enlarged view corresponding to FIG. 3 and schematically showing a third configuration of the semiconductor device according to Embodiment 1.

FIG. 6 is a top view schematically showing a configuration of a heat spreader according to Embodiment 1.

FIG. 7 is a cross-sectional view along a line VII-VII in FIG. 6.

FIG. 8 is a graph schematically showing a relation between a first distance and a shear stress ratio, and a threshold value.

FIG. 9 is a cross-sectional view schematically showing a configuration of a semiconductor device according to a modification of Embodiment 1.

FIG. 10 is an enlarged view of a region X in FIG. 9.

FIG. 11 is a cross-sectional view schematically showing a configuration of a semiconductor device according to Embodiment 2.

FIG. 12 is a top view schematically showing a configuration of a heat spreader according to Embodiment 2.

FIG. 13 is a cross-sectional view along a line XIII-XIII in FIG. 12.

FIG. 14 is a cross-sectional view schematically showing a configuration of a semiconductor device according to Embodiment 3.

FIG. 15 is a block diagram schematically showing a configuration of a power converter according to Embodiment 4.

### DESCRIPTION OF EMBODIMENTS

Embodiments are described hereinafter based on the drawings. In the following, the same or corresponding parts are denoted by the same reference characters, and a description thereof is not herein repeated.

### Embodiment 1

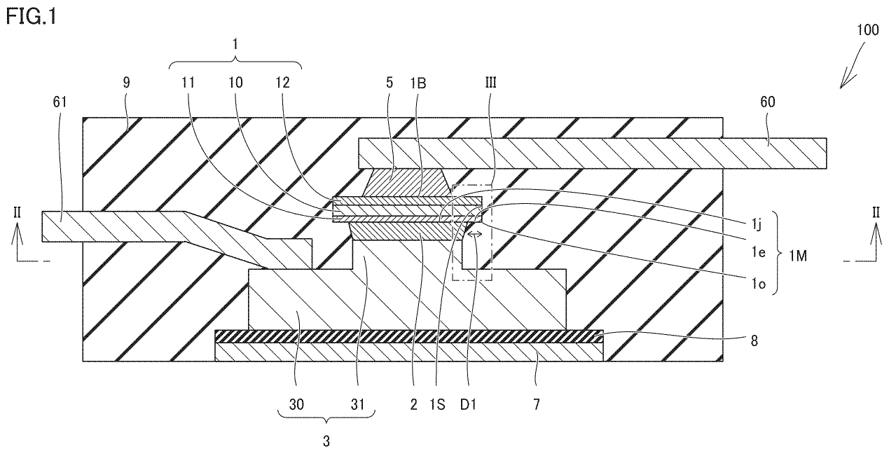

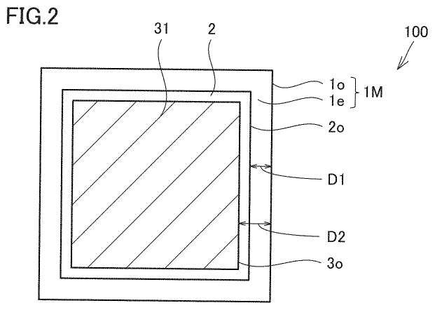

With reference to FIGS. 1 to 8, a configuration of a semiconductor device 100 according to Embodiment 1 is described. FIG. 2 does not show a sealing resin 9 and a second interconnection member 61 for the sake of convenience of description. As shown in FIG. 1, semiconductor device 100 includes a semiconductor element 1, a joint material 2, a heat spreader 3, and a scaling resin 9. Semiconductor device 100 may further include an interconnection joint material 5, a metal layer 7, an insulating layer 8, a first interconnection member 60, and a second interconnection member 61. Semiconductor device 100 is a power semiconductor device used in conjunction with electric power.

As shown in FIG. 1, semiconductor element 1 has a main surface 1M, a back surface 1B, and a side surface 1S. Main surface 1M has a first outer periphery 1o. Main surface 1M has an exposed surface 1e and a joint surface 1j. Exposed surface 1e is located between first outer periphery to and joint material 2. First outer periphery 1o and exposed surface 1e are exposed from joint material 2. First outer periphery 1o and exposed surface 1e are sealed with sealing resin 9. Joint surface 1j is covered with joint material 2.

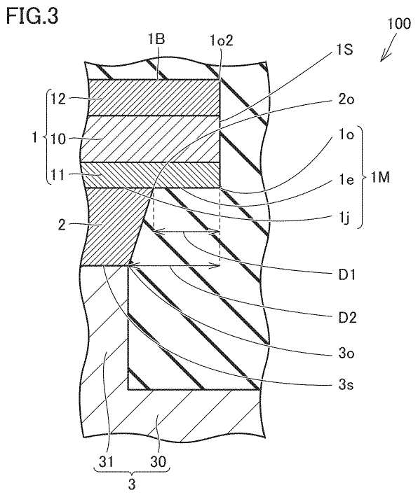

Back surface 1B is opposite to main surface 1M. Back surface 1B is located opposite to main surface 1M with respect to the center of semiconductor element 1. Back surface 1B has a back surface outer periphery 1o2 (see FIG. 3). Back surface outer periphery 1o2 (see FIG. 3) is exposed from joint material 2 and interconnection joint material 5. Back surface outer periphery 1o2 (see FIG. 3) is sealed with sealing resin 9.

As shown in FIG. 1, in the present embodiment, semiconductor element 1 includes an element portion 10, a first electrode 11, and a second electrode 12. Element portion 10 is disposed between first electrode 11 and second electrode 12. First electrode 11 is joined to protrusion 31 by joint material 2. In the present embodiment, first electrode 11 includes main surface 1M. Second electrode 12 is located opposite to first electrode 11 with respect to element portion 10. Second electrode 12 is joined to an interconnection member by interconnection joint material 5. In the present embodiment, second electrode 12 includes back surface 1B.

Semiconductor element 1 is a power semiconductor element used in conjunction with electric power. The material for semiconductor element 1 includes, for example, silicon (Si) or silicon carbide (SiC) or the like. The type of semiconductor element 1 includes, for example, insulated gate bipolar transistor (IGBT), free wheel diode (FWD), and metal oxide semiconductor field effect transistor (MOSFET), and the like. The type of semiconductor element 1 is not limited to them. While semiconductor device 100 in the present embodiment includes one semiconductor element 1, semiconductor device 100 may include a plurality of semiconductor elements 1.

First electrode 11 and second electrode 12 are, for example, at least one of control signal electrode and main electrode. First electrode 11 and second electrode 12 are not limited to them. The material for first electrode 11 and second electrode 12 is a metal having excellent electrical properties and mechanical properties. The material for first electrode 11 and second electrode 12 includes, for example, at least any of aluminum (Al), copper (Cu), silver (Ag), nickel (Ni), and gold (Au). The material for first electrode 11 and second electrode 12 may be an alloy containing, as a main component, at least one of aluminum (Al), copper (Cu), silver (Ag), nickel (Ni), and gold (Au), for example.

As shown in FIG. 1, heat spreader 3 is joined to main surface 1M by joint material 2. Heat spreader 3 includes a main body 30 and a protrusion 31. Main body 30 is located opposite to semiconductor element 1 with respect to joint material 2. In the present embodiment, main body 30 is separated from joint material 2.

As shown in FIG. 1, protrusion 31 is located inside first outer periphery 1o and protrudes from main body 30 toward main surface 1M. Protrusion 31 is joined to main surface 1M by joint material 2. Protrusion 31 and main surface 1M sandwich joint material 2 in between.

The material for heat spreader 3 is a metal having excellent electrical properties and mechanical properties. The material for heat spreader 3 may include, for example, at least any of aluminum (Al), copper (Cu), silver (Ag), nickel (Ni), and gold (Au). The material for heat spreader 3 may be an alloy containing, as a main component, at least one of aluminum (Al), copper (Cu), silver (Ag), nickel (Ni), and gold (Au), for example. The material for heat spreader 3 may be a composite material (Al—SiC) containing silicon carbide (SiC) and aluminum (Al). The material for heat spreader 3 is not limited to them. While semiconductor device 100 in the present embodiment includes one heat spreader 3, semiconductor device 100 may include a plurality of heat spreaders 3.

As shown in FIG. 1, joint material 2 is disposed on main surface 1M. Joint material 2 is disposed between main surface 1M and protrusion 31. Joint material 2 is disposed on joint surface 1j. Joint material 2 does not extend to reach first outer periphery 1o. Semiconductor element 1 is electrically connected to heat spreader 3 by joint material 2.

Interconnection joint material 5 is disposed opposite to joint material 2 with respect to semiconductor element 1. Interconnection joint material 5 is disposed between back surface 1B and interconnection joint material 5. As seen in plan view, interconnection joint material 5 is located inside back surface outer periphery 1o2 (see FIG. 3) and disposed on back surface 1B. In the present embodiment, the direction as seen in plan view is the direction from heat spreader 3 toward semiconductor element 1. Interconnection joint material 5 does not extend to reach back surface outer periphery 1o2 (see FIG. 3).

The material for joint material 2 and interconnection joint material 5 is, for example, a solder for high temperature containing lead (Pb) or tin (Sn), a silver (Ag) nanoparticle paste, or an electrically conductive adhesive containing silver (Ag) particles and epoxy resin, or the like. The material for joint material 2 and interconnection joint material 5 is not limited to them.

As shown in FIG. 1, first interconnection member 60 is joined to second electrode 12 by interconnection joint material 5. Thus, first interconnection member 60 is electrically connected to semiconductor element 1. In the case where semiconductor device 100 does not include interconnection joint material 5, first interconnection member 60 is electrically connected to semiconductor element 1 by a wire or the like, for example. Second interconnection member 61 is joined to heat spreader 3. Thus, second interconnection member 61 is electrically connected to semiconductor element 1 through heat spreader 3 and joint material 2.

The material for first interconnection member 60 and second interconnection member 61 preferably has high electrical conductivity. The material for first interconnection member 60 and second interconnection member 61 is, for example, copper (Cu), aluminum (Al), or an alloy containing copper (Cu) or aluminum (Al), or the like. The material for first interconnection member 60 and second interconnection member 61 is not limited to them.

As shown in FIG. 1, insulating layer 8 is disposed opposite to semiconductor element 1 with respect to heat spreader 3. Insulating layer 8 is joined to main body 30. Insulating layer 8 is disposed between heat spreader 3 and metal layer 7.

Insulating layer 8 electrically insulates heat spreader 3 and metal layer 7 from each other. Insulating layer 8 may be sealed with sealing resin 9, or exposed from sealing resin 9. Insulating layer 8 may not be disposed inside sealing resin 9.

The material for insulating layer 8 is, for example, an organic material filled with a ceramic filler (not shown). The organic material is, for example, epoxy resin, polyimide resin, or cyanate-based resin, or the like. The material for the ceramic filler (not shown) is, for example, alumina (aluminum oxide), aluminum nitride (AlN), or boron nitride (BN), or the like. Insulating layer 8 may be a ceramic substrate, for example. The material for the ceramic substrate is, for example, alumina (aluminum oxide), aluminum nitride (AlN), or boron nitride (BN), or the like. The material for insulating layer 8 is not limited to them.

As shown in FIG. 1, metal layer 7 is disposed opposite to heat spreader 3 with respect to insulating layer 8. Metal layer 7 is connected to insulating layer 8. Metal layer 7 is exposed at least partially from sealing resin 9. Metal layer 7 is located opposite to heat spreader 3 with respect to insulating layer 8 and exposed from sealing resin 9. Metal layer 7 may not be disposed inside sealing resin 9.

The material for metal layer 7 is a metal having excellent thermal properties and mechanical properties. The material for metal layer 7 includes, for example, at least any of aluminum (Al), copper (Cu), nickel (Ni), and gold (Au). The material for metal layer 7 may be an alloy containing, as a main component, at least one of aluminum (Al), copper (Cu), nickel (Ni), and gold (Au), for example.

As shown in FIG. 1, scaling resin 9 seals semiconductor element 1, joint material 2, and heat spreader 3. First interconnection member 60 and second interconnection member 61 are partially exposed from sealing resin 9. Sealing resin 9 is lower in elastic modulus than joint material 2 and interconnection joint material 5. Sealing resin 9 is electrically insulative. The material for scaling resin 9 is, for example, thermosetting resin, urethane resin, epoxy resin, polyimide resin, polyamide resin, polyamide-imide resin, acrylic resin, and rubber, and the like. A plurality of materials for sealing resin 9 may be combined. The material for sealing resin 9 may include, for example, gel-like silicon resin and epoxy resin laid on the silicon resin.

In the present embodiment, the material for sealing resin 9 is a transfer molding resin. Therefore, sealing resin 9 is molded by being pressed and heated.

As shown in FIG. 2, joint material 2 is disposed inside first outer periphery 1o as seen in plan view. Joint material 2 includes a second outer periphery 2o. Second outer periphery 2o is disposed inside first outer periphery 1 o as seen in plan view. Second outer periphery 2o is surrounded by first outer periphery 1o.

As shown in FIGS. 2 and 3, protrusion 31 is disposed inside first outer periphery 1o as seen in plan view. Protrusion 31 includes a protrusion surface 3s. Protrusion surface 3s has a third outer periphery 3o. Third outer periphery 3o is disposed inside first outer periphery to as seen in plan view. Third outer periphery 3o is surrounded by first outer periphery to as seen in plan view. Third outer periphery 3o may be disposed inside second outer periphery 2o as Seen in Plan View.

As shown in FIG. 3, exposed surface 1e is located between first outer periphery 1o and joint material 2. Exposed surface 1e extends inwardly from first outer periphery 1o. Exposed surface 1e extends from first outer periphery 1o to second outer periphery 2o. Joint surface 1j is disposed inside second outer periphery 2o. Side surface 1S is disposed between first outer periphery 1o of main surface 1M and back surface outer periphery 1o2 of back surface 1B. Side surface 1S is exposed from joint material 2 and interconnection joint material 5. Side surface 1S is sealed with sealing resin 9.

As shown in FIG. 3, second outer periphery 2o of joint material 2 is disposed on main surface 1M. A first distance D1 between first outer periphery 1 o and second outer periphery 2o with exposed surface 1e located in between is 50 μm or more and 300 μm or less. As shown in FIGS. 2 and 3, first distance D1 is the shortest distance between first outer periphery to and second outer periphery 2o.

As shown in FIG. 3, protrusion surface 3s is joined to joint material 2. Joint material 2 covers the whole of protrusion surface 3s. Joint material 2 extends to reach third outer periphery 3o of protrusion surface 3s. A second distance D2 between first outer periphery 1 o and third outer periphery 3o in the direction of protrusion surface 3s is 50 μm or more and 300 μm or less. As shown in FIGS. 2 and 3, second distance D2 is the shortest distance between first outer periphery 1o and third outer periphery 3o as seen in plan view.

As long as joint material 2 is disposed inside first outer periphery to as seen in plan view and first distance D1 is 50 μm or more and 300 μm or less, the shape of joint material 2 may be determined appropriately. For example, joint material 2 may be formed so that the size of joint material 2 increases from protrusion surface 3s toward joint surface 1j. Along joint surface 1j, joint material 2 may be wet to expand outward of protrusion surface 3s. First distance D1 may be smaller than second distance D2.

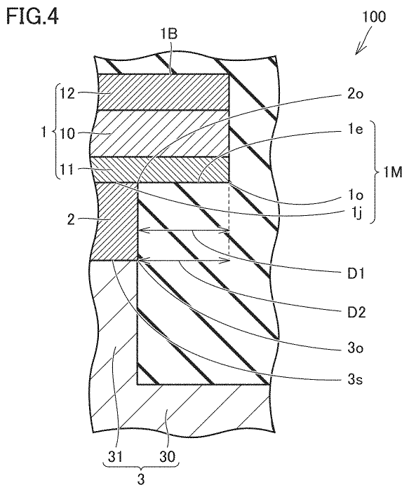

As shown in FIG. 4, joint material 2 may be formed so that the size of joint material 2 on protrusion surface 3s is identical the size thereof on joint surface 1j, for example. Joint material 2 may be wet to expand on joint surface 1j to the same extent as the extent to which joint material 2 is wet to expand on protrusion surface 3s. First distance D1 may be identical to second distance D2. Third outer periphery 3o may overlap second outer periphery 2o as seen in plan view.

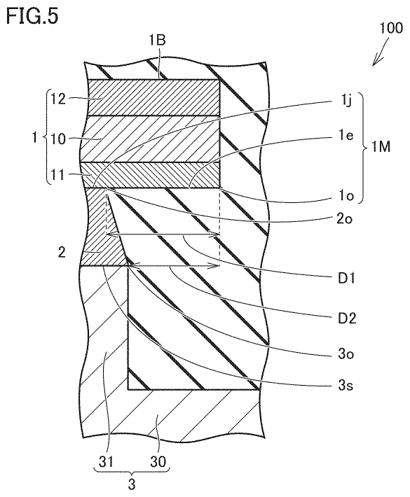

As shown in FIG. 5, joint material 2 may be formed so that the size of joint material 2 decreases from protrusion surface 3s toward joint surface 1j, for example. On joint surface 1j, joint material 2 may be wet to extend inward of protrusion surface 3s. First distance D1 maybe larger than second distance D2. Third outer periphery 3o may be disposed outside second outer periphery 2o as seen in plan view.

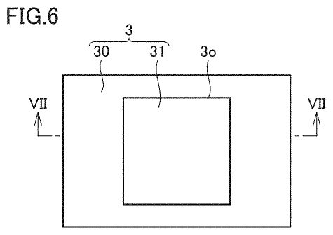

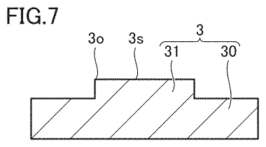

As shown in FIGS. 6 and 7, the outer periphery (third outer periphery 30) of protrusion 31 is disposed inside the outer periphery of main body 30.

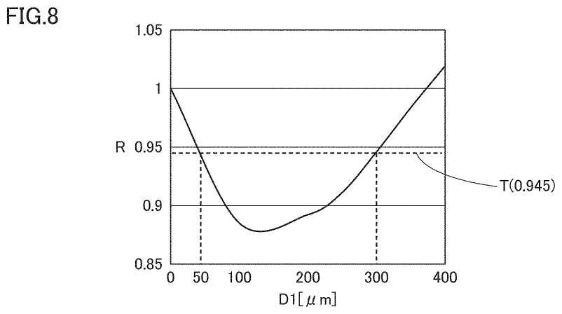

Referring to FIGS. 8 and 3, a relation between first distance D1 and shear stress ratio R is described. In the present embodiment, a shear stress (thermal stress) generated at back surface outer periphery 1o2 of back surface 1B is analyzed to calculate shear stress ratio R. Shear stress ratio R is the magnitude of the shear stress generated at back surface outer periphery 1o2, relative to the magnitude, defined as 1, of the shear stress generated at back surface outer periphery 1o2 when first distance D1 is 0 (i.e., joint material 2 extends to reach first outer periphery 1o).

In FIG. 8, the broken line indicates threshold value T. When shear stress ratio R is larger than threshold value T, malfunctioning occurs in the vicinity of an edge of semiconductor element 1. When shear stress ratio R is larger than threshold value T, sealing resin 9 may be peeled off from semiconductor element 1, at an edge of semiconductor element 1, for example. When shear stress ratio R is larger than threshold value T, cracking may be generated in sealing resin 9 covering the edge of semiconductor element 1, for example. Threshold value T has been calculated by analyzing the structure of semiconductor device 100 in which cracking was actually generated in scaling resin 9. In the present embodiment, threshold value T is 0.945 as shown in FIG. 8.

As shown in FIG. 8, for first distance D1 of 50 μm or more and 300 μm or less, shear stress ratio R is less than or equal to threshold value T. Therefore, when first distance D1 is 50 μm or more and 300 μm or less, occurrence of malfunctioning in the vicinity of an edge of semiconductor element 1 is suppressed.

As shown in FIG. 8, for first distance D1 of less than 50 μm, shear stress ratio R is threshold value T or more. Therefore, when first distance D1 is less than 50 μm, malfunctioning may occur in the vicinity of an edge of semiconductor element 1.

When joint material 2 extends to reach first outer periphery 1o, first distance D1 is 0, and therefore, malfunctioning may occur in the vicinity of an edge of semiconductor element 1.

As shown in FIG. 8, when first distance D1 is larger, shear stress ratio R is threshold value T or more. Therefore, when first distance D1 is larger, malfunctioning may occur in the vicinity of an edge of semiconductor element 1.

Specifically, when first distance D1 is larger than 300 μm, malfunctioning may occur in the vicinity of an edge of semiconductor element 1.

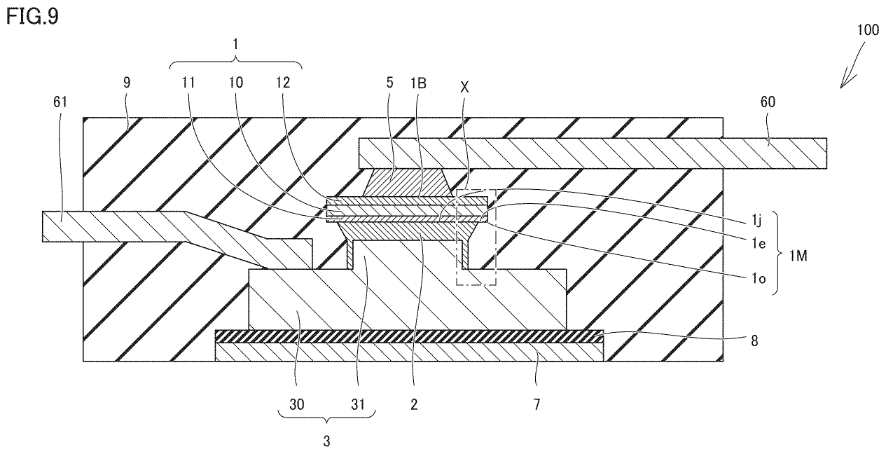

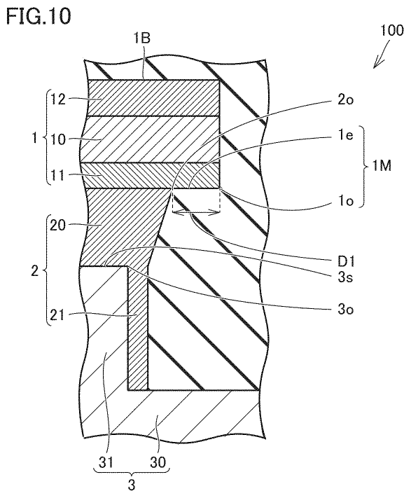

Next, with reference to FIGS. 9 and 10, a configuration of a semiconductor device 100 according to a modification of Embodiment 1 is described. In the following, the modification of Embodiment 1 is described based on FIGS. 9 and 10. In the following, the same or corresponding parts are denoted by the same reference characters, and the description thereof is not herein repeated.

As shown in FIG. 9, in the modification of Embodiment 1, joint material 2 is disposed between main surface 1M and main body 30. As shown in FIG. 10, joint material 2 includes a first joint portion 20 and a second joint portion 21. First joint portion 20 is located inside first outer periphery 1o, and extends from main surface 1M to protrusion surface 3s in the height direction. Second joint portion 21 is located inside first outer periphery 1o, and extends from protrusion surface 3s toward main body 30 in the height direction. Second joint portion 21 may reach main body 30. Second joint portion 21 is disposed outside third outer periphery 3o. As shown in FIGS. 9 and 10, second joint portion 21 may at least partially cover side surface 1S of protrusion 31.

In the following, the functions and advantageous effects of the present embodiment are described.

In semiconductor device 100 according to Embodiment 1, exposed surface 1e is located between first outer periphery to and joint material 2 as shown in FIG. 3. First outer periphery 1o and exposed surface 1e are exposed from joint material 2. Thus, joint material 2 does not reach first outer periphery 1o. Accordingly, a thermal stress generated at an edge of semiconductor element 1 can be reduced.

Referring to FIG. 3, a mechanism of reducing a thermal stress generated at an edge of semiconductor element 1, by the fact that first outer periphery 1o and exposed surface 1e are exposed from joint material 2, is described in detail. As shown in FIG. 3, first outer periphery 1o and exposed surface 1e are exposed from joint material 2. Exposed surface 1e and first outer periphery 1o are sealed with sealing resin 9. Sealing resin 9 is lower in elastic modulus than joint material 2. Therefore, an edge (first outer periphery to) of semiconductor element 1 is more likely to be deformed, relative to the case where joint material 2 reaches first outer periphery 1o. Specifically, an edge of semiconductor element 1 is likely to be deformed in the top to bottom direction. Thus, a thermal stress generated between first outer periphery 1o and sealing resin 9, at an edge of semiconductor element 1, can be reduced, relative to the case where joint material 2 reaches first outer periphery 1o.

As shown in FIG. 3, first outer periphery 1o and exposed surface 1e are exposed from joint material 2, and therefore, a thermal stress generated at an edge of semiconductor element 1 can be reduced. Thus, at an edge of semiconductor element 1, peeling off of semiconductor element 1 from sealing resin 9 can be suppressed, and generation of cracking in sealing resin 9 covering the edge of semiconductor element 1 can be suppressed.

As shown in FIG. 3, protrusion 31 is located inside first outer periphery 1o and protrudes from main body 30 toward main surface 1M. Protrusion 31 is joined to main surface 1M by joint material 2. Semiconductor element 1 and heat spreader 3 are therefore joined directly to each other by joint material 2. Thus, semiconductor element 1 and heat spreader 3 can be arranged precisely.

As shown in FIG. 3, first distance D1 between first outer periphery 1o and second outer periphery 2o with exposed surface 1e located in between is 50 μm or more and 300 μm or less. As shown in FIG. 8, when first distance D1 is 50 μm or more and 300 μm or less, shear stress ratio R is less than threshold value T and therefore, peeling off of sealing resin 9 from semiconductor element 1 can be suppressed at an edge of semiconductor element 1, and generation of cracking in sealing resin 9 covering the edge of semiconductor element 1 can be suppressed. In semiconductor device 100 according to Embodiment 1, first distance D1 is 50 μm or more and 300 μm or less, and therefore, peeling off of scaling resin 9 from semiconductor element 1 can be suppressed at an edge of semiconductor element 1, and generation of cracking in sealing resin 9 covering the edge of semiconductor element 1 can be suppressed.

As shown in FIG. 3, second distance D2 between first outer periphery 1o and third outer periphery 3o in the direction of protrusion surface 3s is 50 μm or more and 300 μm or less. Joint material 2 is disposed between protrusion surface 3s and main surface 1M. As shown in FIGS. 3 and 4, second outer periphery 2o may be disposed, as seen in plan view, to be located outside third outer periphery 3o or to be located at a position overlapping third outer periphery 3o. Therefore, when second distance D2 is 50 μm or more and 300 μm or less, first distance D1 may be 50 μm or more and 300 μm or less. First distance D1 is thus 50 μm or more and 300 μm or less, and therefore, peeling off of sealing resin 9 from semiconductor element 1 can be suppressed at an edge of semiconductor element 1, and generation of cracking in scaling resin 9 covering the edge of semiconductor element 1 can be suppressed.

The material for sealing resin 9 is a transfer molding resin. Therefore, sealing resin 9 may be molded by a transfer molding process.

As shown in FIG. 3, back surface outer periphery 1o2 and side surface 1S are exposed from joint material 2 and interconnection joint material 5. Back surface outer periphery 1o2 and side surface 1S are sealed with sealing resin 9. Scaling resin 9 is lower in elastic modulus than joint material 2 and interconnection joint material 5. Therefore, an edge (back surface outer periphery 1o2 and side surface 1S) of semiconductor element 1 is more likely to be deformed, relative to the case where joint material 2 and interconnection joint material 5 reach back surface outer periphery 1o2 and side surface 1S. Thus, at an edge of semiconductor element 1, a thermal stress generated between back surface outer periphery 1o2/side surface 1S and scaling resin 9 can be reduced, relative to the case where joint material 2 and interconnection joint material 5 reach back surface outer periphery 1o2 and side surface 1S.

If joint material 2 is disposed only in the space between main surface 1M and protrusion surface 3s in the height direction, increase of joint material 2 is likely to cause extension of joint material 2 on main surface 1M, which may result in joint material 2 reaching first outer periphery to. In this case, a thermal stress generated between first outer periphery 1o and sealing resin 9 may be increased.

In semiconductor device 100 according to the modification of Embodiment 1, as shown in FIG. 10, joint material 2 includes second joint portion 21. Second joint portion 21 extends from protrusion surface 3s toward main body 30 in the height direction. Thus, even when the amount of joint material 2 is increased, second joint portion 21 can flow from protrusion surface 3s toward main body 30. Therefore, extension of joint material 2 on main surface 1M is suppressed, and therefore, extension of joint material 2 to first outer periphery to can be suppressed, even when the amount of joint material 2 is increased. Exposed surface 1e can thus be exposed from joint material 2 even when the amount of joint material 2 is increased. Semiconductor device 100 can thus be manufactured easily even when the amount of joint material 2 is increased, and therefore, the cost for manufacturing semiconductor device 100 can be reduced.

### Embodiment 2

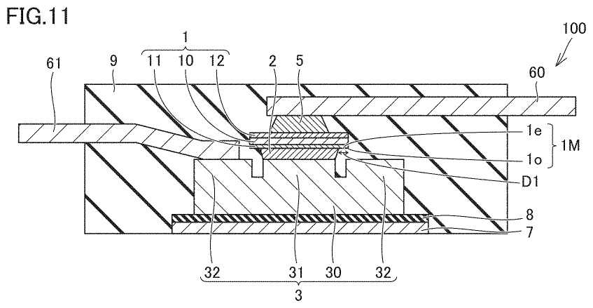

Next, with reference to FIGS. 11 to 13, a configuration of a semiconductor device 100 according to Embodiment 2 is described. Embodiment 2 is identical in configuration as well as functions and advantageous effects to Embodiment 1 as described above, unless particularly specified. Therefore, the same features as those of Embodiment 1 as described above are denoted by the same reference characters, and the description thereof is not herein repeated.

As shown in FIG. 11, according to Embodiment 2, heat spreader 3 further includes a peripheral portion 32. Peripheral portion 32 protrudes from main body 30 toward main surface 1M.

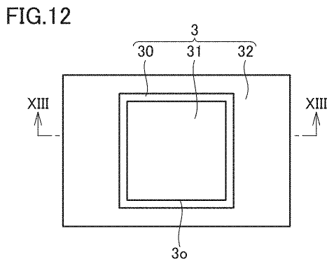

As shown in FIG. 12, peripheral portion 32 is separated from joint material 2. Peripheral portion 32 surrounds protrusion 31 with a gap between protrusion 31 and peripheral portion 32.

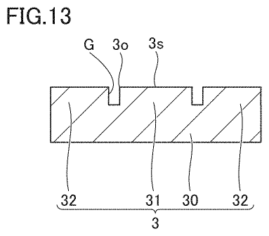

As shown in FIG. 13, peripheral portion 32 is identical in thickness to protrusion 31. A groove G may be formed in a plate-like member to form heat spreader 3 including main body 30, protrusion 31, and peripheral portion 32. Protrusion 31 is separated from main body 30 by groove G.

In the following, the functions and advantageous effects of the present embodiment are described.

In semiconductor device 100 according to Embodiment 2, heat spreader 3 further includes peripheral portion 32 as shown in FIG. 12. Peripheral portion 32 surrounds protrusion 31 with a gap between protrusion 31 and peripheral portion 32. Cutting of heat spreader 3 can therefore be reduced, relative to the case where protrusion 31 is not surrounded by peripheral portion 32. Accordingly, the process required for working on heat spreader 3 may be simplified. Therefore, the cost for manufacturing semiconductor device 100 can be reduced.

### Embodiment 3

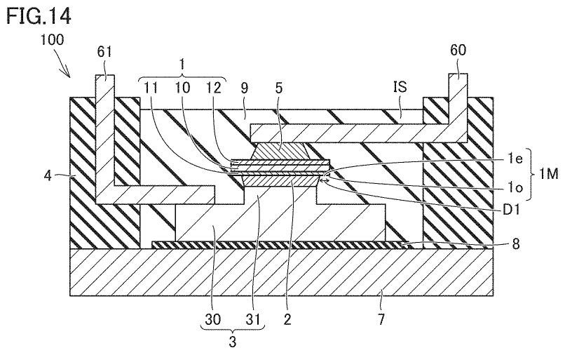

Next, with reference to FIG. 14, a configuration of a semiconductor device 100 according to Embodiment 3 is described. Embodiment 3 is identical in configuration as well as functions and advantageous effects to Embodiment 1 as described above, unless particularly specified. Therefore, the same features as those of Embodiment 1 as described above are denoted by the same reference characters, and the description thereof is not herein repeated.

As shown in FIG. 14, semiconductor device 100 further includes a case 4. Case 4 includes an internal space IS. Heat spreader 3, joint material 2, and semiconductor element 1 are arranged in internal space IS and, in this state, internal space IS of case 4 is filled with scaling resin 9. Semiconductor device 100 according to Embodiment 3 differs from semiconductor device 100 according to Embodiment 1 in that the former includes case 4.

Case 4 is joined to metal layer 7 by a joint material (not shown). Case 4 and metal layer 7 form a housing of semiconductor device 100. The material for case 4 is an electrically insulating material that can be injection-molded and has high heat resistance. Specifically, the material for case 4 includes at least any of polyphenylene sulfide, polybutylene terephthalate, liquid crystal resin, and fluorocarbon-based resin, for example.

In the following, the functions and advantageous effects of the present embodiment are described.

Regarding semiconductor device 100 according to Embodiment 3, semiconductor device 100 further includes case 4 as shown in FIG. 14. Case 4 and metal layer 7 form the housing of semiconductor device 100. Therefore, a cooler and external interconnections/wires (not shown) can be connected easily to the housing of semiconductor device 100. The process for manufacturing semiconductor device 100 is thus simplified, and therefore, the cost for manufacturing semiconductor device 100 can be reduced.

### Embodiment 4

In the present embodiment, the semiconductor devices according to Embodiments 1 to 3 as described above are applied to a power converter. While the present disclosure is not limited to a specific power converter, Embodiment 4 is described below in connection with a case where the present disclosure is applied to a three-phase inverter.

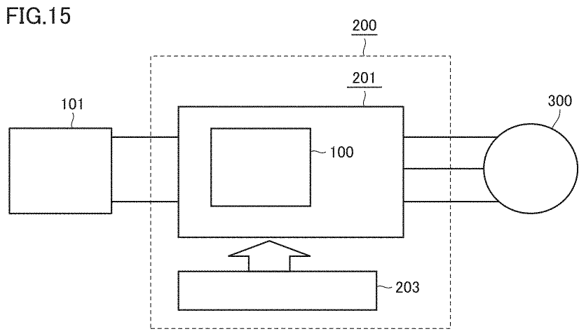

FIG. 15 is a block diagram showing a configuration of a power conversion system to which the power converter according to the present embodiment is applied.

The power conversion system shown in FIG. 15 includes a power supply 101, a power converter 200, and a load 300. Power supply 101 is a DC power supply and supplies DC power to power converter 200. Power supply 101 may be configured in the form of any of various power supplies such as DC system, solar battery, storage battery, or in the form of a rectifier circuit and/or an AC/DC converter or the like connected to an AC system, for example. Power supply 101 may also be configured in the form of a DC/DC converter that converts DC power output from a DC power system to predetermined electric power.

Power converter 200 is a three-phase inverter connected between power supply 101 and load 300, converts DC power supplied from power supply 101 to AC power and supplies the AC power to load 300. As shown in FIG. 15, power converter 200 includes a main conversion circuit 201 that converts DC power to AC power and outputs the AC power, and a control circuit 203 that outputs, to main conversion circuit 201, a control signal that controls main conversion circuit 201.

Load 300 is a three-phase electric motor driven by AC power supplied from power converter 200. Load 300 is not limited to a specific use, but is an electric motor to be mounted on any of various electrical devices, and is used, for example, as an electric motor for hybrid vehicle, electric vehicle, railroad vehicle, elevator, or air conditioner.

In the following, details of power converter 200 are described. Main conversion circuit 201 includes switching elements and freewheeling diodes (not shown), and the switching elements are switched to cause DC power supplied from power supply 101 to be converted to AC power and cause the AC power to be supplied to load 300. While the specific circuit configuration of main conversion circuit 201 is any of various configurations, main conversion circuit 201 according to the present embodiment is a two-level three-phase full-bridge circuit that can be configured to include six switching elements and six free-wheeling diodes connected in anti-parallel with respective switching elements. At least any of the switching elements and the freewheeling diodes of main conversion circuit 201 is the switching element or free-wheeling diode of semiconductor device 100 corresponding to the semiconductor device according to any of Embodiments 1 to 3 as described above. For each pair of switching elements included in the six switching elements, the switching elements of each pair are connected in series to each other to form an upper arm and a lower arm, and the upper arm and the lower arm form each phase (U phase, V phase, W phase) of the full-bridge circuit. An output terminal of each pair of the upper and lower arms, i.e., three output terminals of main conversion circuit 201, are connected to load 300.

Main conversion circuit 201 includes a drive circuit (not shown) that drives each switching element, and the drive circuit may be contained in semiconductor device 100, or the drive circuit may be provided separately from semiconductor device 100. The drive circuit generates a drive signal that drives the switching elements of main conversion circuit 201, and supplies the drive signal to a control electrode of the switching elements of main conversion circuit 201. Specifically, in accordance with a control signal from control circuit 203 described later herein, a drive signal that causes a switching element to be an ON state and a drive signal that causes a switching element to be an OFF state are output to the control electrode of each switching element. When the switching element is to be kept in the ON state, the drive signal is a voltage signal (ON signal) higher than or equal to a threshold voltage for the switching element and, when the switching element is to be kept in the OFF state, the drive signal is a voltage signal (OFF signal) of less than ow equal to the threshold value for the switching element.

Control circuit 203 controls the switching elements of main conversion circuit 201 such that desired electric power is supplied to load 300. Specifically, the time for which each switching element of main conversion circuit 201 should be in the ON state (ON time) is calculated, based on electric power to be supplied to load 300. For example, PWM control for modifying the ON time of the switching element depending on the voltage to be output, for example, can be used to control main conversion circuit 201. A control command (control signal) is output to the drive circuit of main conversion circuit 201, such that, at each point of time, an ON signal is output to a switching element to be brought into the ON state and an OFF signal is output to a switching element to be brought into the OFF state. In accordance with this control signal, the drive circuit outputs the ON signal or the OFF signal as the drive signal to the control electrode of each switching element.

In the power converter according to the present embodiment, the semiconductor devices according to Embodiments 1 to 3 can be applied to serve as semiconductor device 100 forming main conversion circuit 201, to thereby implement the power converter in which a thermal stress generated at an edge of the semiconductor element can be reduced and the semiconductor element and the heat spreader can be arranged precisely.

While an example is described above in connection with the present embodiment in which the present disclosure is applied to a two-level three-phase inverter, the present disclosure is not limited to this but may be applied to various power converters. While the power converter is a two-level power converter in the present embodiment, the power converter may be a three-level or multi-level power converter and, when electric power is to be supplied to a single-phase load, the present disclosure may be applied to a single-phase inverter. Moreover, when electric power is to be supplied to a DC load or the like, the present disclosure may also be applied to DC/DC converter or AC/DC converter.

The power converter to which the present disclosure is applied is not limited to a power converter for which the above-described load is an electric motor, but may be used as a power supply apparatus for electrical discharge machining device or laser processing machine, or induction heating cooking device or noncontact power feed system, or may also be used as a power conditioner for a photovoltaic system or power storage system, for example.

It should be construed that the embodiments disclosed herein am given by way of illustration in all respects, not by way of limitation. It is intended that the scope of the present disclosure is defined by claims, not by the description above, and encompasses all modifications and variations equivalent in meaning and scope to the claims.

### REFERENCE SIGNS LIST

1 semiconductor element; 1M main surface; 1e exposed surface; 1o first outer periphery; 2 joint material; 2o second outer periphery; 3 heat spreader; 3o third outer periphery; 4 case; 9 sealing resin; 30 main body; 31 protrusion; 32 peripheral portion; 101 power supply; 200 power converter; 201 main conversion circuit; 203 control circuit; 300 load; D1 first distance; D2 second distance; IS internal space

1. A semiconductor device comprising:
a semiconductor element including a main surface having a first outer periphery;
a joint material disposed on the main surface;
a heat spreader joined to the main surface by the joint material; and
a sealing resin sealing the semiconductor element, the joint material, and the heat spreader, wherein
the heat spreader includes
a main body disposed opposite to the semiconductor element with respect to the joint material, and
a protrusion located inside the first outer periphery and protruding from the main body toward the main surface,
the protrusion includes a protrusion surface and is joined to the main surface by the joint material,
the semiconductor element includes a first electrode joined to the protrusion by the joint material,
the main surface has an exposed surface located between the first outer periphery and the joint material,
the first outer periphery and the exposed surface are exposed from the joint material and sealed with the sealing resin,
the first electrode includes the main surface having the exposed surface,
the joint material includes a first joint portion and a second joint portion that contact each other at a position of an extension from the protrusion surface,
the first joint portion is located inside the first outer periphery and extends from the main surface to the protrusion surface in a height direction,
at the position of the extension from the protrusion surface, the joint portion increases in dimension from the protrusion surface toward the main surface, and
the second joint portion is located inside the first outer periphery and extends from the protrusion surface toward the main body in the height direction.

2. The semiconductor device according to claim 1, wherein
the joint material includes a second outer periphery disposed on the main surface, and
a distance between the first outer periphery and the second outer periphery with the exposed surface located in between is 50 μm or more and 300 μm or less.

3. The semiconductor device according to claim 2, wherein
the protrusion includes a protrusion surface having a third outer periphery and joined to the joint material, and
a distance between the first outer periphery and the third outer periphery in a direction of the protrusion surface is 50 μm or more and 300 μm or less.

4. The semiconductor device according to claim 1, wherein
the heat spreader further includes a peripheral portion protruding from the main body toward the main surface and separated from the joint material, and
the peripheral portion surrounds the protrusion with a gap between the peripheral portion and the protrusion.

5. The semiconductor device according to claim 1, wherein a material for the sealing resin is a transfer molding resin.

6. The semiconductor device according to claim 1, further comprising a case including an internal space, wherein
with the heat spreader, the joint material, and the semiconductor element disposed in the internal space, the internal space of the case is filled with the sealing resin.

7. A power converter comprising:
a main conversion circuit including the semiconductor device according to claim 1, to convert and output input power; and
a control circuit to output, to the main conversion circuit, a control signal that controls the main conversion circuit.
